(19) United States
(12) Patent Application Publication
(10) Pub. No.: US 2026/0352212 A1
(43) Pub. Date: Nov. 5, 2026

(54) Dome Switch of a Capacitance Module

(71) Applicant: Cirque Corporation, Sandy, UT (US)

(72) Inventor: Brian Monson, Farmington, UT (US)

(73) Assignee: Cirque Corporation, Sandy, UT (US)

(21) Appl. No.: 19/195,389

(22) Filed: Apr. 30, 2025

(51) Int. Cl. H03K 17/96; G06F 3/0354; H01H 13/14; H01H 13/52

(52) U.S. Cl. CPC H03K 17/962; H01H 13/14; G06F 3/03547; H01H 13/52

(57) ABSTRACT

An electronic device may include a capacitance module, a set of capacitance electrodes disposed on a first layer of the capacitance module, and a dome switch connected to an underside surface of the capacitance module, the capacitance module having a hinged side connected to a connecting surface of the electronic device and a free side opposite to the hinged side. The dome element may include a dome structure having a base attached to the underside of the capacitance module, the dome structure forming a collapsible surface, the dome structure and the underside surface of the capacitance module defining a cavity.

### FIELD OF THE DISCLOSURE

This disclosure relates generally to systems and methods for detecting inputs on capacitive touch pads. In particular, this disclosure relates to systems and methods for determining click inputs using a hinged touch pad.

### BACKGROUND

Dome switches are commonly integrated into keyboards. A typical dome switch assembly includes a snap-acting metallic dome positioned above a contact pad. In its default state, the dome is elevated and electrically isolated from the pad. When downward pressure is applied, the dome deforms and snaps into a depressed position, establishing physical and electrical contact with the underlying pad. This closes an electrical circuit, generating a switching signal and delivering tactile feedback. Upon release, the dome returns to its original shape, reopening the circuit.

Although dome switches are widely used in keyboards, they are subject to wear and performance degradation over time. Repeated actuation can erode the conductive interface between the dome and the contact pad due to factors such as mechanical fatigue, oxidation, or material abrasion, leading to unreliable contact. As a result, the switch may intermittently fail to close the circuit upon actuation, causing missed inputs and requiring repair or replacement to maintain functional reliability.

An example of a dome switch is disclosed in U.S. Pat. No. 9,443,672 issued to Steven J. Martisauskas. This reference discloses touch sensitive mechanical keyboards and processes for routing the drive and sense lines of the touch sensitive keyboard using patterned dome switches. The keyboard can include on or more mechanical keys having a touch sensor located within or beneath a keycap. The keyboard can further include a dome switch beneath each keycap to detect a depression of the corresponding key. The dome switch can be formed from an elastic (or malleable) material and can include patterned conductive traces within the elastic material. The patterned conductive traces can be used to route stimulation signals and sense signals to and from the touch sensor. In some examples, a first end of the patterned conductive traces can be coupled to the drive and sense lines of the touch sensor and a second end of the patterned conductive traces can be coupled to a flexible circuit or PCB.

An example of a dome switch included in an input apparatus is described in U.S. Patent No. 2013/0100030 issued to Oleg Los, et al. This reference discloses an example keypad including a dome switch assembly having a dome aligned relative to a first trace pattern and a second trace pattern of a printed circuit board and a key aligned with the dome. The key is depressible between an initial position, an intermediate position, and a depressed position, where the key is to deflect the dome to electrically couple the first and second trace patterns when the key is in the depressed position. A touch sensing film detects a touch on a keycap of the key when the key is in the initial position and a pressure sensing film detects a force on the keycap when the key is in the intermediate position.

Each of these references are herein incorporated by reference for all that they disclose.

### SUMMARY

In one embodiment, an electronic device may include a capacitance module; a set of capacitance electrodes disposed on a first layer of the capacitance module; a dome switch connected to an underside surface of the capacitance module; the capacitance module having a hinged side connected to a connecting surface of the electronic device and a free side opposite to the hinged side; the dome switch comprising a dome element comprised of a elastically deformable material; the dome element having a dome structure having a base attached to the underside; the dome structure forming a collapsible surface; the dome structure and the underside surface of the capacitance module define a cavity; the dome element being flexible to move the collapsible surface into the cavity towards the underside surface.

The electronic device may include a first dome electrode on the underside surface and positioned within the cavity.

The collapsible surface of the dome element may be constructed to form an electrical connection with the first dome electrode when an actuation force causes the collapsible surface to make physical contact with the first dome electrode.

The collapsible surface of the dome may be constructed to move towards the first dome electrode but not make physical contact with the first dome electrode.

The electronic device may include a dielectric positioned between the collapsible surface of the dome structure and the first dome electrode in the cavity.

The electronic device may include a processor in communication with the first dome electrode and memory where the memory includes programmed instructions that cause the processor, when executed, to take a first measurement with the first dome electrode; determine to generate a click event based, at least in part, on the first measurement.

The electronic device may include a second dome electrode.

The programmed instructions may be configured to cause the second dome electrode to take a second measurement.

In one embodiment, an electronic device may include a capacitance module, a set of capacitance electrodes disposed on a first layer of the capacitance module, and a dome switch connected to an underside surface of the capacitance module, the capacitance module having a hinged side connected to a connecting surface of the electronic device and a free side opposite to the hinged side. The dome switch may include a dome element made of an elastically deformable material. The dome element may include a dome structure having a base attached to the underside of the capacitance module, the dome structure forming a collapsible surface, the dome structure and the underside surface of the capacitance module defining a cavity. A first dome electrode disposed on the underside surface may be positioned within the cavity, with a second dome electrode on the underside surface and positioned within the cavity. The dome element may be flexible to move the collapsible surface into the cavity towards the first dome electrode and the second dome electrode under an applied force.

The elastically deformable material may be electrically conductive.

The elastically deformable material may include a rubber material.

The collapsible surface of the dome element may be constructed to form an electrical connection with the first dome electrode when an actuation force causes the collapsible surface to make physical contact with the first dome electrode.

The collapsible surface may be constructed to move towards the first dome electrode but not make physical contact with the first dome electrode or the second dome electrode.

A dielectric may be positioned between the collapsible surface of the dome structure and the first dome electrode and the second dome electrode in the cavity.

The electronic device may include a processor in communication with the first dome electrode, the second dome electrode, and memory. The memory may include programmed instructions that cause the processor, when executed, to take a first measurement with the first dome electrode, take a second measurement with the second dome electrode, and determine to generate a click based, at least in part, on the first measurement and the second measurement.

The electronic device may include a processor in communication with the first dome electrode, the second dome electrode, and memory. The memory may include programmed instructions that cause the processor, when executed, to take a first measurement with the first dome electrode, and determine to generate a click based, at least in part, on the first measurement.

Determining whether to generate a click event may include comparing the first measurement and the second measurement against predetermined threshold values.

The first measurement may be an electric voltage measurement, and the second measurement may be a capacitance measurement.

The first measurement may be a capacitance measurement, and the second measurement may be a capacitance measurement.

The programmed instructions may cause the processor, when executed, to apply an electrical signal to the first dome electrode, take a first capacitance measurement with the second dome electrode, and determine whether to generate a click event based, at least in part, on the first capacitance measurement.

The programmed instructions may cause the processor, when executed, to take a second capacitance measurement after taking the first capacitance measurement.

Determining whether to generate a click event may include comparing the first capacitance measurement and the second capacitance measurement against predetermined threshold values.

Determining whether to generate a click event may include comparing the first capacitance measurement to the second capacitance measurement.

The electronic device may include shielding material disposed around the first and second dome electrodes, the shielding material that reduces electromagnetic interference on the first and second dome electrodes.

The second dome electrode may be disposed around the first dome electrode in a concentric ring shape wherein the space between the first dome electrode and the second dome electrode forms an annular shape.

In another embodiment, a method for determining a click input on a capacitance module may include receiving a first measurement from a first dome electrode disposed within a dome cavity of a dome switch located on a free side of a hinged touchpad, receiving a second measurement from a second dome electrode within the dome cavity, and determining to generate a touch pad click event based, at least in part, on the first measurement and the second measurement.

The first measurement may be an electric voltage measurement, and the second measurement may be a capacitance measurement.

The first measurement may be a capacitance measurement, and the second measurement may be a capacitance measurement.

In another embodiment, a computer-program product for determining a click input on a capacitance module may include a non-transitory computer-readable medium storing instructions executable by a processor to receive a first measurement from a dome electrode disposed within a dome cavity of a dome switch located on a free side of a hinged touchpad, receive a second measurement from a second dome electrode within the dome cavity, and determine to generate a touch pad click event based, at least in part, on the first measurement and the second measurement.

The first measurement may be an electric voltage measurement, and the second measurement may be a capacitance measurement.

The first measurement may be a capacitance measurement, and the second measurement may be a capacitance measurement.

### BRIEF DESCRIPTION OF THE DRAWINGS

FIG. 1 depicts an example of an electronic device in accordance with the disclosure.

FIG. 2 depicts an example of a substrate with a first set of electrodes and a second set of electrodes in accordance with the disclosure.

FIG. 3 depicts an example of a touch pad in accordance with the disclosure.

FIG. 4 depicts an example of a touch screen in accordance with the disclosure.

FIG. 5 depicts an example of a hinged touchpad in accordance with the disclosure.

FIG. 6 depicts an example of a hinged touchpad in accordance with the disclosure.

FIG. 7 depicts an example of a dome switch in accordance with the disclosure.

FIG. 8 depicts an example of a dome switch in accordance with the disclosure.

FIG. 9 depicts an example of a dome switch in accordance with the disclosure.

FIG. 10 depicts an example of a dome switch in accordance with the disclosure.

FIG. 11 depicts an example of a dome switch in accordance with the disclosure.

FIG. 12 depicts an example of a capacitance graph in accordance with the disclosure.

FIG. 13 depicts an example of voltage and capacitance graphs in accordance with the disclosure.

FIG. 14 depicts an example of a capacitance graph in accordance with the disclosure.

FIG. 15 depicts an example of a method for determining whether to generate a click event in accordance with the disclosure.

FIG. 16 depicts an example of a method for determining whether to generate a click event in accordance with the disclosure.

FIG. 17 depicts an example of a method for determining whether to generate a click event in accordance with the disclosure.

FIG. 18 depicts an example of dome switch electrodes in accordance with the disclosure.

FIG. 19 depicts an example of dome switch electrodes in accordance with the disclosure.

FIG. 20 depicts an example of dome switch electrodes in accordance with the disclosure.

FIG. 21 depicts an example of dome switch electrodes in accordance with the disclosure.

FIG. 22 depicts an example of dome switch electrodes in accordance with the disclosure.

FIG. 23 depicts an example of a method for determining whether to generate a click event in accordance with the disclosure.

FIG. 24 depicts an example of a method for determining whether to generate a click event in accordance with the disclosure.

FIG. 25 depicts an example of a method for determining whether to generate a click event in accordance with the disclosure.

While the disclosure is susceptible to various modifications and alternative forms, specific embodiments have been shown by way of example in the drawings and will be described in detail herein. However, it should be understood that the disclosure is not intended to be limited to the particular forms disclosed. Rather, the intention is to cover all modifications, equivalents and alternatives falling within the spirit and scope of the invention as defined by the appended claims.

### DETAILED DESCRIPTION OF THE INVENTION

This description provides examples, and is not intended to limit the scope, applicability, or configuration of the invention. Rather, the ensuing description will provide those skilled in the art with an enabling description for implementing embodiments of the invention. Various changes may be made in the function and arrangement of elements.

Thus, various embodiments may omit, substitute, or add various procedures or components as appropriate. For instance, it should be appreciated that the methods may be performed in an order different than that described, and that various steps may be added, omitted, or combined. Also, aspects and elements described with respect to certain embodiments may be combined in various other embodiments. It should also be appreciated that the following systems, methods, devices, and software may individually or collectively be components of a larger system, wherein other procedures may take precedence over or otherwise modify their application.

For purposes of this disclosure, the term “aligned” generally refers to being parallel, substantially parallel, or forming an angle of less than 35.0 degrees. For purposes of this disclosure, the term “transverse” generally refers to perpendicular, substantially perpendicular, or forming an angle between 55.0 and 125.0 degrees. For purposes of this disclosure, the term “length” generally refers to the longest dimension of an object. For purposes of this disclosure, the term “width” generally refers to the dimension of an object from side to side and may refer to measuring across an object perpendicular to the object's length.

For purposes of this disclosure, the term “electrode” may generally refer to a portion of an electrical conductor intended to be used to make a measurement, and the terms “route” and “trace” generally refer to portions of an electrical conductor that are not intended to make a measurement. For purposes of this disclosure in reference to circuits, the term “line” generally refers to the combination of an electrode and a “route” or “trace” portions of the electrical conductor. For purposes of this disclosure, the term “Tx” generally refers to a transmit line, electrode, or portions thereof, and the term “Rx” generally refers to a sense line, electrode, or portions thereof.

For the purposes of this disclosure, the term “electronic device” may generally refer to devices that can be transported and include a battery and electronic components. Examples may include a laptop, a desktop, a mobile phone, an electronic tablet, a personal digital device, a watch, a gaming controller, a gaming wearable device, a wearable device, a measurement device, an automation device, a security device, a display, a computer mouse, a vehicle, an infotainment system, an audio system, a control panel, another type of device, an athletic tracking device, a tracking device, a card reader, a purchasing station, a kiosk, or combinations thereof.

It should be understood that use of the terms “capacitance module,” “touch pad” and “touch sensor” throughout this document may be used interchangeably with “capacitive touch sensor,” “capacitive sensor,” “capacitance sensor,” “capacitive touch and proximity sensor,” “proximity sensor,” “touch and proximity sensor,” “touch panel,” “trackpad,” “touch pad,” and “touch screen.” The capacitance module may be incorporated into an electronic device.

It should also be understood that, as used herein, the terms “vertical,” “horizontal,” “lateral,” “upper,” “lower,” “left,” “right,” “inner,” “outer,” etc., can refer to relative directions or positions of features in the disclosed devices and/or assemblies shown in the Figures. For example, “upper” or “uppermost” can refer to a feature positioned closer to the top of a page than another feature. These terms, however, should be construed broadly to include devices and/or assemblies having other orientations, such as inverted or inclined orientations where top/bottom, over/under, above/below, up/down, and left/right can be interchanged depending on the orientation.

In some cases, the capacitance module is located within a housing. The capacitance module may be underneath the housing and capable of detecting objects outside of the housing. In examples, where the capacitance module can detect changes in capacitance through a housing, the housing is a capacitance reference surface. For example, the capacitance module may be disclosed within a cavity formed by a keyboard housing of a computer, such as a laptop or other type of computing device, and the sensor may be disposed underneath a surface of the keyboard housing. In such an example, the keyboard housing adjacent to the capacitance module is the capacitance reference surface. In some examples, an opening may be formed in the housing, and an overlay may be positioned within the opening. In this example, the overlay is the capacitance reference surface. In such an example, the capacitance module may be positioned adjacent to a backside of the overlay, and the capacitance module may sense the presence of the object through the thickness of the overlay. For the purposes of this disclosure, the term “reference surface” may generally refer to a surface through which a pressure sensor, a capacitance sensor, or another type of sensor is positioned to sense a pressure, a presence, a position, a touch, a proximity, a capacitance, a magnetic property, an electric property, another type of property, or another characteristic, or combinations thereof that indicates an input. For example, the reference surface may be a housing, an overlay, or another type of surface through which the input is sensed. In some examples, the reference surface has no moving parts. In some examples, the reference surface may be made of any appropriate type of material, including, but not limited to, plastics, glass, a dielectric material, a metal, another type of material, or combinations thereof.

For the purposes of this disclosure, the term “display” may generally refer to a display or screen that is not depicted in the same area as the capacitive reference surface. In some cases, the display is incorporated into a laptop where a keyboard is located between the display and the capacitive reference surface. In some examples where the capacitive reference surface is incorporated into a laptop, the capacitive reference surface may be part of a touch pad. Pressure sensors may be integrated into the stack making up the capacitance module. However, in some cases, the pressure sensors may be located at another part of the laptop, such as under the keyboard housing, but outside of the area used to sense touch inputs, on the side of the laptop, above the keyboard, to the side of the keyboard, at another location on the laptop, or at another location. In examples where these principles are integrated into a laptop, the display may be pivotally connected to the keyboard housing. The display may be a digital screen, a touch screen, another type of screen, or combinations thereof. In some cases, the display is located on the same device as the capacitive reference surface, and in other examples, the display is located on another device that is different from the device on which the capacitive reference surface is located. For example, the display may be projected onto a different surface, such as a wall or projector screen. In some examples, the reference surface may be located on an input or gaming controller, and the display is located on a wearable device, such as a virtual reality or augmented reality screen. In some cases, the reference surface and the display are located on the same surface, but on separate locations on that surface. In other examples, the reference surface and the display may be integrated into the same device, but on different surfaces. In some cases, the reference surface and the display may be oriented at different angular orientations with respect to each other.

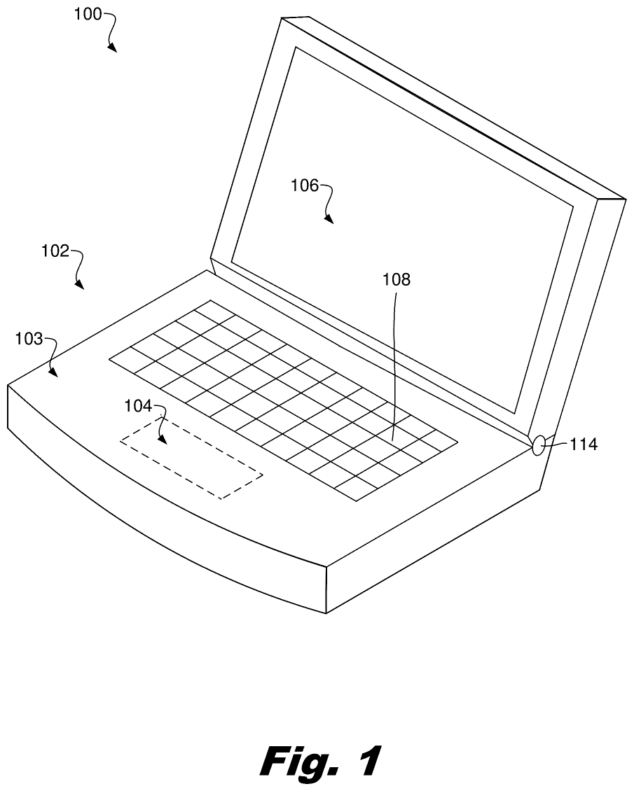

FIG. 1 depicts an example of an electronic device 100. In this example, the electronic device is a laptop. In the illustrated example, the electronic device 100 includes input components, such as a keyboard 102 and a capacitive module, such as a touch pad 104, that are incorporated into a housing 103. The electronic device 100 also includes a display 106. A program operated by the electronic device 100 may be depicted in the display 106 and controlled by a sequence of instructions that are provided by the user through the keyboard 102 and/or through the touch pad 104. An internal battery (not shown) may be used to power the operations of the electronic device 100.

The keyboard 102 includes an arrangement of keys 108 that can be individually selected when a user presses on a key with a sufficient force to cause the key 108 to be depressed towards a switch located underneath the keyboard 102. In response to selecting a key 108, a program may receive instructions on how to operate, such as a word processing program determining which types of words to process. A user may use the touch pad 104 to give different types of instructions to the programs operating on the computing device 100. For example, a cursor depicted in the display 106 may be controlled through the touch pad 104. A user may control the location of the cursor by sliding his or her hand along the surface of the touch pad 104. In some cases, the user may move the cursor to be located at or near an object in the computing device's display and give a command through the touch pad 104 to select that object. For example, the user may provide instructions to select the object by tapping the surface of the touch pad 104 one or more times.

The touch pad 104 is a capacitance module that includes a stack of layers disposed underneath the keyboard housing, underneath an overlay that is fitted into an opening of the keyboard housing, or underneath another capacitive reference surface. In some examples, the capacitance module is located in an area of the keyboard's surface where the user's palms may rest while typing. The capacitance module may include a substrate, such as a printed circuit board or another type of substrate. One of the layers of the capacitance module may include a sensor layer that includes a first set of electrodes oriented in a first direction and a second layer of electrodes oriented in a second direction that is transverse the first direction. These electrodes may be spaced apart and/or electrically isolated from each other. The electrical isolation may be accomplished by deposited at least a portion of the electrodes on different sides of the same substrate or providing dedicated substrates for each set of electrodes. Capacitance may be measured at the overlapping intersections between the different sets of electrodes. However, as an object with a different dielectric value than the surrounding air (e.g., finger, stylus, etc.) approach the intersections between the electrodes, the capacitance between the electrodes may change. This change in capacitance and the associated location of the object in relation to the capacitance module may be calculated to determine where the user is touching or hovering the object within the detection range of the capacitance module. In some examples, the first set of electrodes and the second set of electrodes are equidistantly spaced with respect to each other. Thus, in these examples, the sensitivity of the capacitance module is the same in both directions. However, in other examples, the distance between the electrodes may be non-uniformly spaced to provide greater sensitivity for movements in certain directions.

In some cases, the display 106 is mechanically separate and movable with respect to the keyboard with a connection mechanism 114. In these examples, the display 106 and keyboard 102 may be connected and movable with respect to one another. The display 106 may be movable within a range of 0 degrees to 180 degrees or more with respect to the keyboard 102. In some examples, the display 106 may fold over onto the upper surface of the keyboard 102 when in a closed position, and the display 106 may be folded away from the keyboard 102 when the display 106 is in an operating position. In some examples, the display 106 may be orientable with respect to the keyboard 102 at an angle between 35 to 135 degrees when in use by the user. However, in these examples, the display 106 may be positionable at any angle desired by the user.

In some examples, the display 106 may be a non-touch sensitive display. However, in other examples at least a portion of the display 106 is touch sensitive. In these examples, the touch sensitive display may also include a capacitance module that is located behind an outside surface of the display 106. As a user's finger or other object approaches the touch sensitive screen, the capacitance module may detect a change in capacitance as an input from the user.

While the example of FIG. 1 depicts an example of the electronic device being a laptop, the capacitance sensor and touch surface may be incorporated into any appropriate device. A non-exhaustive list of devices includes, but is not limited to, a desktop, a display, a screen, a kiosk, a computing device, an electronic tablet, a smart phone, a location sensor, a card reading sensor, another type of electronic device, another type of device, or combinations thereof.

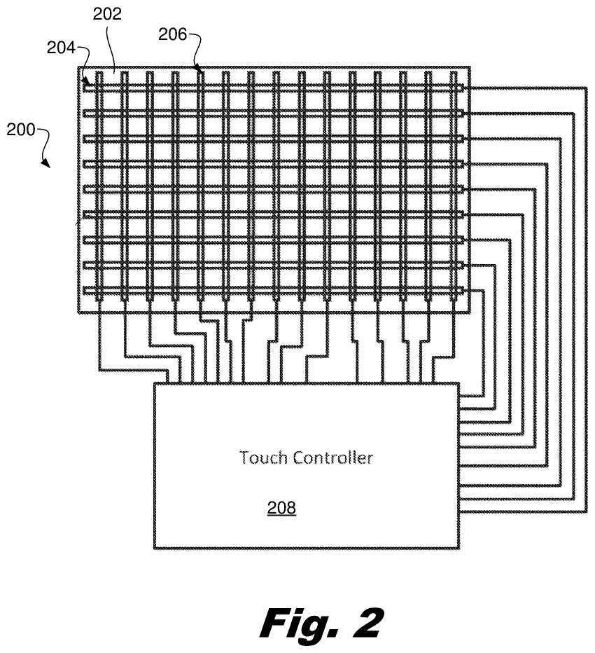

FIG. 2 depicts an example of a portion of a capacitance module 200. In this example, the capacitance module 200 may include a substrate 202, first set 204 of electrodes, and a second set 206 of electrodes. The first and second sets 204, 206 of electrodes may be oriented to be transverse to each other. Further, the first and second sets 204, 206 of electrodes may be electrically isolated from one another so that the electrodes do not short to each other. However, where electrodes from the first set 204 overlap with electrodes from the second set 206, capacitance can be measured. The capacitance module 200 may include one or more electrodes in the first set 204 or the second set 206. Such a substrate 202 and electrode sets may be incorporated into a touch screen, a touch pad, a location sensor, a gaming controller, a button, and/or detection circuitry.

In some examples, the capacitance module 200 is a mutual capacitance sensing device. In such an example, the substrate 202 has a set 204 of row electrodes and a set 206 of column electrodes that define the touch/proximity-sensitive area of the component. In some cases, the component is configured as a rectangular grid of an appropriate number of electrodes (e.g., 8-by-6, 16-by-12, 9-by-15, or the like).

As shown in FIG. 2, the capacitance module 208 includes a capacitance controller 208. The capacitance controller 208 may include at least one of a central processing unit (CPU), a digital signal processor (DSP), an analog front end (AFE) including amplifiers, a peripheral interface controller (PIC), another type of microprocessor, and/or combinations thereof, and may be implemented as an integrated circuit, a field programmable gate array (FPGA), an application specific integrated circuit (ASIC), a combination of logic gate circuitry, other types of digital or analog electrical design components, or combinations thereof, with appropriate circuitry, hardware, firmware, and/or software to choose from available modes of operation.

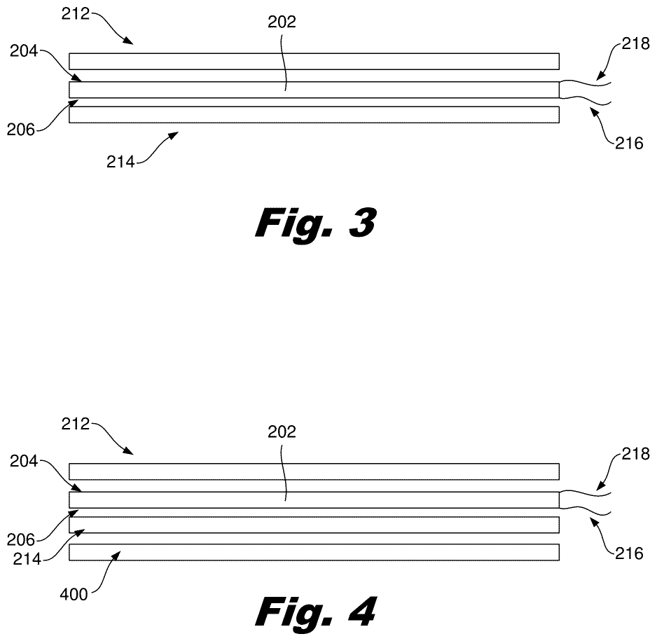

In some cases, the capacitance controller 208 includes at least one multiplexing circuit to alternate which of the sets 204, 206 of electrodes are operating as drive electrodes and sense electrodes. The driving electrodes can be driven one at a time in sequence, or randomly, or drive multiple electrodes at the same time in encoded patterns. Other configurations are possible such as a self-capacitance mode where the electrodes are driven and sensed simultaneously. Electrodes may also be arranged in non-rectangular arrays, such as radial patterns, linear strings, or the like. A shield layer (see FIG. 3) may be provided beneath the electrodes to reduce noise or other interference. The shield may extend beyond the grid of electrodes. Other configurations are also possible.

In some cases, no fixed reference point is used for measurements. The touch controller 208 may generate signals that are sent directly to the first or second sets 204, 206 of electrodes in various patterns.

In some cases, the component does not depend upon an absolute capacitive measurement to determine the location of a finger (or stylus, pointer, or other object) on a surface of the capacitance module 200. The capacitance module 200 may measure an imbalance in electrical charge to the electrode functioning as a sense electrode which can, in some examples, be any of the electrodes designated in either set 204, 206 or, in other examples, with dedicated-sense electrodes. When no pointing object is on or near the capacitance module 200, the capacitance controller 208 may be in a balanced state, and there is no signal on the sense electrode. When a finger or other pointing object creates imbalance because of capacitive coupling, a change in capacitance may occur at the intersections between the sets of electrodes 204, 206 that make up the touch/proximity sensitive area. In some cases, the change in capacitance is measured. However, in alternative example, the absolute capacitance value may be measured.

While this example has been described with the capacitance module 200 having the flexibility of the switching the sets 204, 206 of electrodes between sense and transmit electrodes, in other examples, each set of electrodes is dedicated to either a transmit function or a sense function.

FIG. 3 depicts an example of a substrate 202 with a first set 204 of electrodes and a second set 206 of electrodes deposited on the substrate 202 that is incorporated into a capacitance module. The first set 204 of electrodes and the second set 206 of electrodes may be spaced apart from each other and electrically isolated from each other. In the example depicted in FIG. 3, the first set 204 of electrodes is deposited on a first side of the substrate 202, and the second set 206 of electrodes is deposited on the second side of the substrate 202, where the second side is opposite the first side and spaced apart by the thickness of the substrate 202. The substrate may be made of an electrically insulating material thereby preventing the first and second sets 204, 206 of electrodes from shorting to each other. As depicted in FIG. 2, the first set 204 of electrodes and the second set 206 of electrodes may be oriented transversely to one another. Capacitance measurements may be taken where the intersections with the electrodes from the first set 204 and the second set 206 overlap. In some examples, a voltage may be applied to the transmit electrodes and the voltage of a sense electrode that overlaps with the transmit electrode may be measured. The voltage from the sense electrode may be used to determine the capacitance at the intersection where the sense electrode overlaps with the transmit electrode.

In the example of FIG. 3 depicting a cross section of a capacitance module, the substrate 202 may be located between a capacitance reference surface 212 and a shield 214. The capacitance reference surface 212 may be a covering that is placed over the first side of the substrate 202 and that is at least partially transparent to electric fields. As a user's finger or stylus approach the capacitance reference surface 212, the presence of the finger or the stylus may affect the electric fields on the substrate 202. With the presence of the finger or the stylus, the voltage measured from the sense electrode may be different than when the finger or the stylus are not present. As a result, the change in capacitance may be measured.

The shield 214 may be an electrically conductive layer that shields electric noise from the internal components of the electronic device. This shield may prevent influence on the electric fields on the substrate 202. In some cases, the shield is solid piece of material that is electrically conductive. In other cases, the shield has a substrate and an electrically conductive material disposed on at least one substrate. In yet other examples, the shield is layer in the touch pad that performs a function and also shields the electrodes from electrically interfering noise. For example, in some examples, a pixel layer in display applications may form images that are visible through the capacitance reference surface, but also shields the electrodes from the electrical noise.

The voltage applied to the transmit electrodes may be carried through an electrical connection 216 from the touch controller 208 to the appropriate set of electrodes. The voltage applied to the sense electrode through the electric fields generated from the transmit electrode may be detected through the electrical connection 218 from the sense electrodes to the touch controller 208.

While the example of FIG. 3 has been depicted as having both sets of electrodes deposited on a substrate, one set of electrodes deposited on a first side and a second set of electrodes deposited on a second side; in other examples, each set of electrodes may be deposited on its own dedicated substrate.

Further, while the examples above describe a touch pad with a first set of electrodes and a second set of electrodes; in some examples, the capacitance module has a single set of electrodes. In such an example, the electrodes of the sensor layer may function as both the transmit and the receive electrodes. In some cases, a voltage may be applied to an electrode for a duration of time, which changes the capacitance surrounding the electrode. At the conclusion of the duration of time, the application of the voltage is discontinued. Then a voltage may be measured from the same electrode to determine the capacitance. If there is no object (e.g., finger, stylus, etc.) on or in the proximity of the capacitance reference surface, then the measured voltage off of the electrode after the voltage is discontinued may be at a value that is consistent with a baseline capacitance. However, if an object is touching or in proximity to the capacitance reference surface, then the measured voltage may indicate a change in capacitance from the baseline capacitance.

In some examples, the capacitance module has a first set of electrodes and a second set of electrodes and is communication with a controller that is set up to run both mutual capacitance measurements (e.g., using both the first set and the second set of electrodes to take a capacitance measurement) or self-capacitance measurements (e.g., using just one set of electrodes to take a capacitance measurement).

FIG. 4 depicts an example of a capacitance module incorporated into a touch screen. In this example, the substrate 202, sets of electrodes 204, 206, and electrical connections 216, 218 may be similar to the arrangement described in conjunction with FIG. 3. In the example of FIG. 4, the shield 214 is located between the substrate 202 and a display layer 400. The display layer 400 may be a layer of pixels or diodes that illuminate to generate an image. The display layer may be a liquid crystal display, a light emitting diode display, an organic light emitting diode display, an electroluminescent display, a quantum dot light emitting diode display, an incandescent filaments display, a vacuum fluorescent display, a cathode gas display, another type of display, or combinations thereof. In this example, the shield 214, the substrate 202, and the capacitance reference surface 212 may all be at least partially optically transparent to allow the image depicted in the display layer to be visible to the user through the capacitance reference surface 212. Such a touch screen may be included in a monitor, a display assembly, a laptop, a mobile phone, a mobile device, an electronic tablet, a dashboard, a display panel, an infotainment device, another type of electronic device, or combinations thereof.

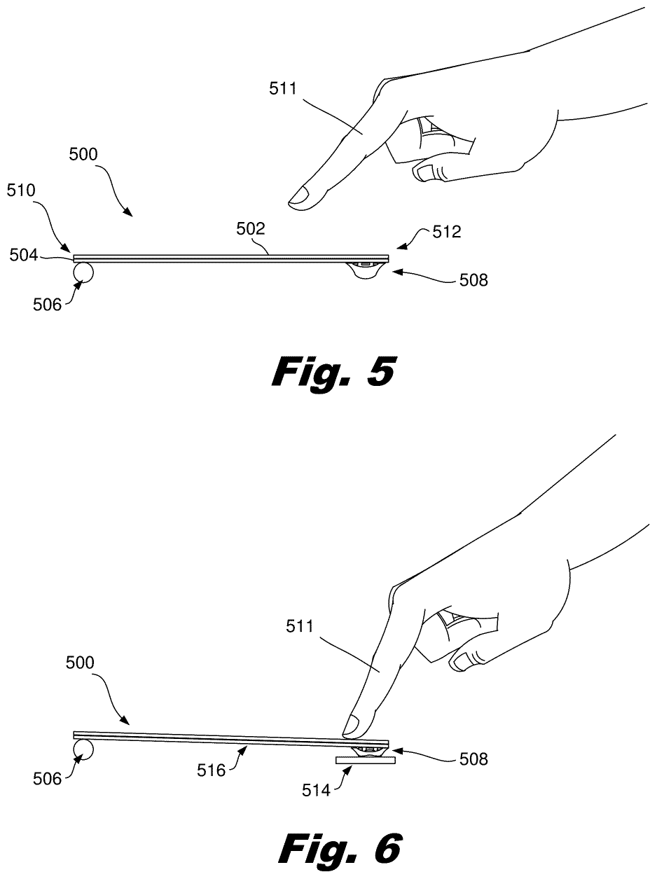

FIG. 5 depicts an example of a hinged touchpad 500 in accordance with the disclosure. The touchpad 500 includes an overlay 502 coupled to a capacitance module 504. The capacitance module 504 is pivotally mounted to a hinge 506 located on a hinged side 510. On the opposite, free side 512 of the touchpad 500, a capacitive dome switch 508 is positioned beneath the capacitance module 504. A user input object (e.g., a finger) is shown above to the overlay 502.

FIG. 6 depicts the hinged touchpad 500 with the free side 512 pushed into a cavity of the electronic device. When the user input object 511 applies downward pressure to the free side of the touchpad 500, the touchpad 500 may pivot about the hinge 506, causing the free side 512 to deflect. This angular displacement may push the capacitive dome switch 508 into a surface 514 near the underside of the capacitance module 504, which in turn generates a switching signal indicating a click input. The surface 514 may be a metal bracket associated with the touchpad 500, a bottom of the cavity formed in the electronic device, another surface, or combinations thereof.

The capacitive dome switch 508 may generate a switching signal in multiple ways. In one example, as pressure is applied, the dome may deform and displace towards electrodes positioned within the dome cavity. For example, at least one dome electrode may be formed on the underside 516 of the capacitance module 504, which may measure a difference capacitance value as the metal of the dome switch gets closer to the dome electrode as the dome switch is compressed.

In some implementations where there are multiple dome electrodes located within the cavity formed by the dome switch the electrodes in the dome cavity may form a mutual capacitance sensor that detects the dome's proximity. A processor coupled to the mutual capacitance sensor may be calibrated to register a click input when the dome electrode measures a change in capacitance that exceeds a predetermined threshold, as determined by changes in mutual capacitance.

In other implementations, the electrodes in the dome cavity may detect dome proximity using self-capacitance. A processor coupled to the electrodes may sequentially apply an electrical waveform to each electrode and measure the resulting voltage over time to determine its capacitance. In some examples as the dome approaches, the capacitance of the electrodes increases. The processor may be calibrated to register a click input when the dome reaches pre-determined threshold, based on the detected capacitance change.

In some implementations, the electrodes may be arranged such that the dome makes physical contact with a first electrode while remaining spaced from a second electrode in the dome cavity. Contact with the first electrode may close a circuit, prompting a connected processor to register a click input. The second electrode may detect the dome's proximity using self-capacitance or mutual capacitance with the processor calibrated to register a click when the dome reaches its actuation apex based on the capacitance change. Using both contact-based and capacitive measurements may provide redundancy. If physical contact with the first electrode fails to register a click, the processor may rely on the capacitance data from the second electrode to determine whether the dome switch is compressed.

In some examples that utilize mutual capacitance measurements, the dome may have a single electrode within the cavity. The single electrode may be a transmit electrode or a sense electrode. In embodiments where the single electrode is a sense electrode, the dome may be a transmit electrode. In some examples where the single electrode is a transmit electrode, the dome may be the sense electrode.

In other examples where mutual capacitance is used, a first electrode and a second electrode may be within the cavity. In such an example, one of the first electrode and the second electrode may be a transmit electrode and the other electrode may be sense electrode.

In some examples, the dome is a self-capacitance electrode and there are no dome electrodes in the cavity. In such an embodiment, the dome may take a measurement to determine how much the dome has been collapsed. The click event may be triggered in response to a self-capacitance measurement that reflects that the dome is just partially collapsed. In other examples, the click event may be triggered in response to a self-capacitance measurement that reflects that the dome is completely collapsed.

In implementations that utilize both contact-based and capacitive measurements, the processor may measure a voltage of the first electrode and a capacitance of the second electrode. Voltage measurement at the first electrode may reduce processing overhead compared to capacitance measurement. However, in some implementations, the processor may measure the capacitance of both electrodes. As the dome contacts the first electrode, the capacitance of the first electrode may approach a saturation point or otherwise change in a predictable way, which may also be used to confirm actuation of the capacitive dome switch 508.

The overlay 502 may be made of an electrically transparent material which permits electric fields from the capacitance module 504 to pass through. When user input contacts or approaches the overlay 502, the capacitance module 504 may detect its position through the overlay. In some examples, the overlay 502 may be formed from glass, plastic, another electrically transparent material, or combinations thereof. In some examples, the capacitance module 504 may determine the location of the user input, and the dome switch may determine that a sufficient pressure has been applied to the free end of the touchpad to trigger the click.

The underside 516 of the capacitance module 504 may span from the hinged side 510 to the free side 512 and may move as a unitary object. The hinged side 516 may pivot about an axis resulting the hinged side experiencing relatively less movement than the free side when the user applies a force to the free side. In some cases, the entire touchpad (from the hinged side to the free side) move together in response to the user input.

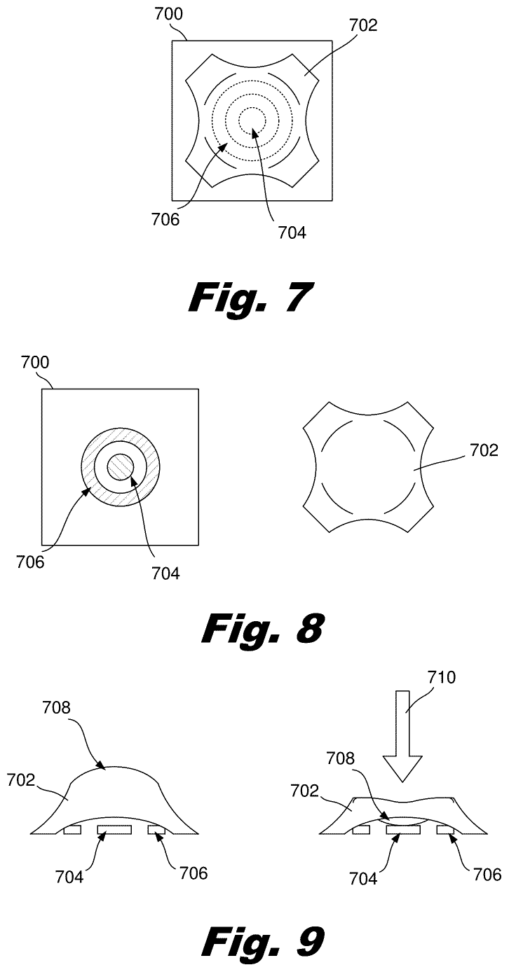

FIG. 7 depicts an example of a capacitive dome switch in accordance with the disclosure. The switch includes a dome structure 702 attached to a base 700. A first dome electrode 704 and a second dome electrode 706 are positioned on the base 700 within the cavity defined by the dome structure 702. For clarity, FIG. 8 shows the base 700 and the dome structure 702 as separate components.

The base may be the underside of the capacitance module. In such an example, the first dome electrode and the second dome electrode may be deposited on the same layer as the controller, memory, a ground connection, NFC antenna, or another component that may be located on the underside of the capacitance module.

In some examples, the first dome electrode, the second dome electrode, the dome structure, or another portion of the dome switch may be in communication with the controller. In some examples, both the first dome electrode and the second dome electrode are in electrical communication with the same controller as the capacitance electrodes of the capacitance module that determine the location of the user input. Such embodiments may leverage the capacitance logic already existing in the capacitance logic already existing in the touch pad. Such usage of the touchpad's capacitance logic may reduce the number of controllers associated with the touchpad. For example, in such an embodiment, the capacitance logic may be used to determine an input location, a user pressure, a user click, another input characteristic, or combinations thereof.

The first dome electrode, the second dome electrode, the dome structure, or combinations thereof of may be in communication with the controller, and the controller may send a signal to a haptic actuator to generate a haptic movement in response to the compressed dome switch. The compressed dome switch may be determined by the dome structure shorting to the first dome electrode as a result of the physical contact between the dome structure and the first electrode, by the dome structure shorting to the second dome electrode as a result of the physical contact between the dome structure and the second electrode, as a result of a capacitance measurement taken with the first dome electrode, as a result of a capacitance measurement taken with the second dome electrode, as a result of a capacitance measurement taken with the dome structure, or combinations thereof. In some examples, the haptic actuator may also be connected to the touchpad and when electrical shorting occurs as a result of the user input, the compression may close a circuit that directs enough current to the haptic actuator to cause the haptic actuator to trigger. However, in some cases, when the capacitance value measured with a dome electrode that is not constructed to make physical contact with the dome structure exceeds the predetermined threshold, the controller may send an instruction to cause sufficient electrical energy to the haptic actuator to trigger the haptic actuator. Such a system may allow the click response to occur in an event where the dome switch is compressed, but the physical contact between the appropriate dome electrode and the dome structure fails to occur. In some cases, a coating or a residue from the manufacturing process may be inadvertently applied over the appropriate dome electrode and may cause the electrical shorting to occur. However, the disclosed dome switch may provide a redundancy that allows the dome switch to activate the haptic actuator in cause of such a flaw. In some cases, the residue may eventually wear away, allowing the electrical shorting to occur as intended, but the construction of the disclosed dome switch may provide redundancy entire such residue wears away.

FIG. 9 depicts a side view of the dome switch depicted in FIGS. 7 and 8, illustrating the first dome electrode 704 and second dome electrode 706 located within the cavity of the dome structure 702. When a compressive force 710 is applied, a dome apex 708 of the dome structure 702 may deflect and make physical contact with the first dome electrode 704.

In the illustrated example, the first dome electrode 704 is centered within the cavity and surrounded by the second dome electrode 706, which has a ring shape. In some examples, the first dome electrode and the second dome electrode are concentric. In other implementations, electrode shapes and arrangements may vary, including configurations such as parallel traces, interleaved comb structures, other shapes, or combinations thereof.

The shape and positioning of the first and second dome electrodes 704, 706 may be determined based on the location of the dome apex 708. For example, the first dome electrode 704 may be positioned such that the apex 708 makes contact only with the first electrode when depressed, avoiding contact with the second electrode 706.

In other examples, electrode geometry and relative orientation may depend on the sensing method. In some mutual capacitance sensor embodiments, the electrodes may be positioned such that the dome apex 708 does not contact either electrode during actuation.

In the dome switch depicted in FIGS. 7-9, the electrodes are arranged such that the apex 708 physically contacts the first dome electrode 704 when actuated. This contact may close an electrical circuit, causing a connected processor to register a click. Simultaneously, the second dome electrode 706 may detect the proximity of the apex 708 using self-capacitance sensing or mutual capacitance offering an alternative or redundant way to detect a user input.

In some implementations, a processor may prioritize contact-based signals over capacitive signals. In other implementations, a processor may prioritize capacitive signals over contact-based signals. In yet other implementations, a processor may use both a contact-based signal and a capacitive signal to confirm a valid click input.

In some examples, the dome structure 702 may be formed of a conductive material which can be sensed capacitively. In other examples, the dome structure may be formed of a different material and then selectively coated with a conductive material such that the dome apex 708 may be sensed capacitively and close an electrical circuit.

In some implementations, the dome structure 702 may be mechanically or adhesively affixed to the base 700. In some examples, the base may be part of the underside surface of the capacitance module. In other examples, the base may be part of a structure that is attached to the underside surface of the capacitance module. In yet another example, the base may be a structure that is adjacent to the capacitance module, but not connected to the capacitance module. In some implementations, the dome structure 702 may be grounded or electrically floating, depending on the sensing configuration.

By having the dome switch connected to the underside of the capacitance module, the click response may include less latency because the dome structure, the first dome electrode, and/or the second dome electrode may be in hard-wire communication with the controller that is also located on the underside of the capacitance module. In such an example, the dome switch or one of its components are located on the same unitary surface that is uninterrupted with surfaces that move relative to one another that would otherwise involve a complex electrical connection that would electrically connect the dome switch to the controller on the underside of the capacitance module. In other situations where the dome switch is located on a different surface than the underside of the capacitance module the dome switch may need to be in communication with a different controller or in wireless communication with controller on the underside of the capacitance controller. The controller on the underside of the capacitance module may be configured to determined capacitance measurements that are taken with the set of capacitance electrodes to determine the location of user touch inputs. The capacitance logic of the controller of the capacitance module may be leveraged to instruct the dome switch to take capacitance measurements thereby reducing the latency that would otherwise be involved if a second controller were utilized or the dome switch was located on a separate surface than the underside surface, a movable surface with respect to the underside of the capacitance module, a surface adjacent to the underside surface, another surface, or combinations thereof.

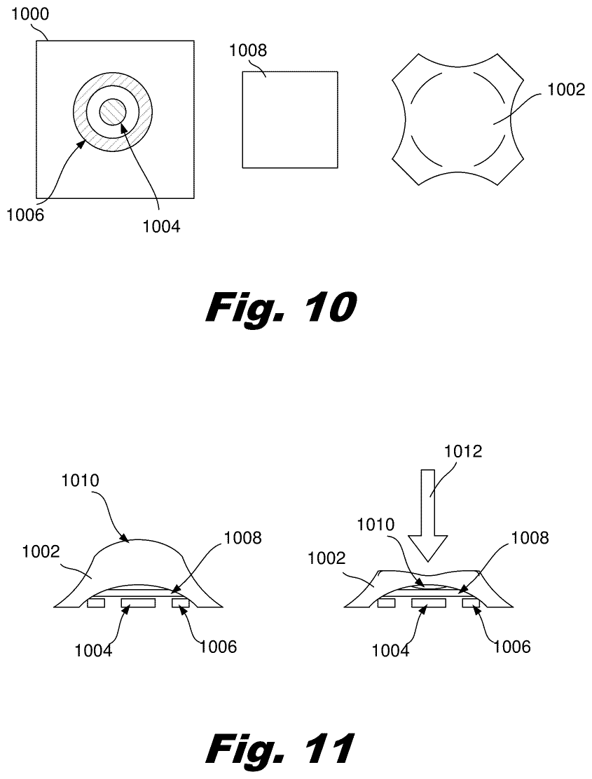

FIG. 10 depicts an example of a dome switch incorporating a dielectric layer 1008. The dome switch includes a base 1000 with a first dome electrode 1004 and a second dome electrode, the dielectric layer 1008 and a dome structure 1002. For illustrative purposes, the base 1000, dielectric layer 1008, and dome structure 1002 are shown as separate components. In some examples, the dielectric layer is an inadvertent residue covering at least a portion of one of the dome electrodes as a result of a manufacturing process, a coating, paint, an insulator, another material, or combinations thereof.

FIG. 11 depicts the dome switch from the side. The dome structure 1002 defines an internal cavity in which the first dome electrode 1004, second dome electrode 1006, and dielectric layer 1008 are positioned. When a downward force 1012 is applied to the dome structure 1002, the dome apex 1010 deflects and makes physical contact with the dielectric layer 1008.

The dielectric layer 1008 may be formed from a material which is electrically transparent to electric fields, allowing the first and second dome electrodes 1004, 1006 to sense the dome apex 1010 capacitively through the layer. The dielectric layer 1008 prevents direct electrical contact between the dome apex 1010 and the electrodes, thereby protecting the electrodes from electrical shorting or capacitive saturation.

The dielectric layer 1010 may enhance tactile feedback during actuation. While the dome structure inherently produces a tactile response as it snaps between its normal and depressed positions, the feedback may be more pronounced when the dome apex physically contacts the dielectric layer.

A dielectric layer may be formed from an electrically transparent material which provides a desirable tactile response. Example materials for dielectric layers include but are not limited to, polyimide, polyethylene terephthalate, polycarbonate, silicone rubber, other materials, or combinations thereof.

In implementations where a dome switch incorporates a dielectric layer, the dome electrodes may capacitively detect the position of the dome apex to determine a click input. In some examples, the dome electrodes may function as individual capacitance sensors with simultaneous activation and measurement cycles, enabling redundant measurements. In other examples, the self-capacitance cycles of each electrode may be offset, reducing the likelihood of missed inputs. Alternatively, the electrodes may be arranged as a mutual capacitance sensor to detect the dome apex based on changes in the electric field between the electrodes.

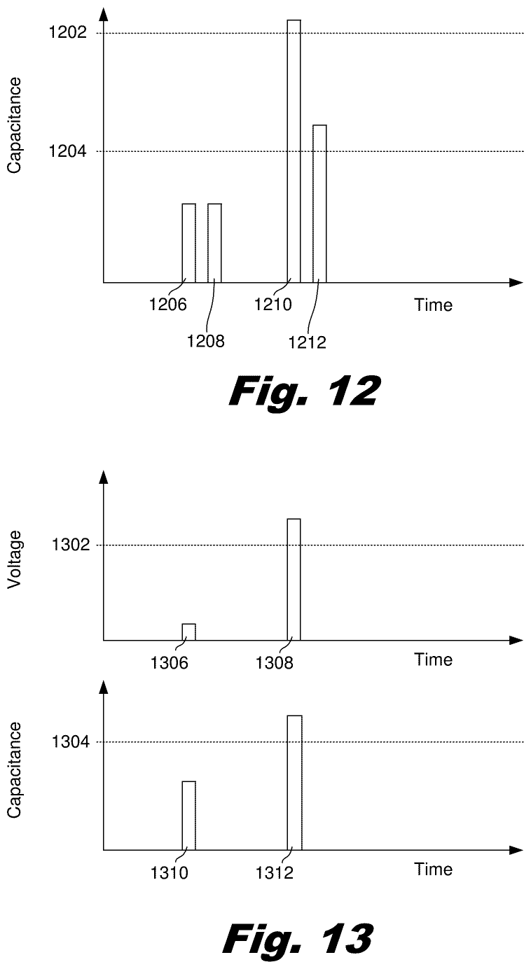

FIG. 12 depicts an example of a capacitance signal graph in accordance with the disclosure. In this example, the horizontal axis represents time, and the vertical axis represents capacitance as measured. A click detection threshold 1204 and a saturation threshold 1202 are marked on the vertical axis. Four measurements are shown as vertical bars which includes a first measurement 1206, a second measurement 1208, a third measurement 1210, and a fourth measurement 1212.

When the dome switch is in its unpressed state, capacitance values at both electrodes may remain below the click detection threshold 1204, as shown by the first and second measurements 1206, 1208. When the dome is pressed, the apex contacts the first dome electrode, resulting in a sharp increase in measured capacitance. The third measurement 1210 exceeds both the click detection threshold 1204 and the saturation threshold 1202, which may indicate physical contact and potential sensor saturation. At the same time, the fourth measurement 1212, corresponding to the second dome electrode, which is not contacted by the dome, rises above the click detection threshold 1204 but remains below the saturation threshold 1202.

This behavior illustrates a dual-channel sensing model in which the first dome electrode detects direct physical contact (saturation), and the second electrode senses proximity only. The differential between these two readings may provide an additional layer of click-state confirmation and help distinguish between contact and near-contact states.

A processor connected to the dome electrodes may register a click event when one or more measured capacitance values exceed the click detection threshold. In some implementations, the processor may further analyze saturation behavior or cross-reference multiple sensor values to improve accuracy and reduce false positives.

In some examples, the click detection threshold 1204 and saturation threshold 1202 may be fixed, predetermined values which are calibrated once. In other examples, thresholds may be adaptive over time or recalibrated periodically.

FIG. 13 depicts an example of a voltage graph and a capacitance signal graph in accordance with the disclosure. In this example, the voltage graph represents voltage on a vertical axis, and the capacitance signal graph represents capacitance on a vertical axis. Both the voltage and capacitance signal graphs represent time on a horizontal axis. A contact detection threshold 1302 is marked on the vertical axis of the voltage graph, and a proximity detection threshold 1304 is marked on the vertical axis of the capacitance signal graph. The graphs illustrate signal behavior from two different sensing electrodes during dome switch actuation.

In this example, the first electrode operates as a contact-based sensor, and the second electrode operates as a capacitance proximity sensor. A first voltage measurement 1306 and a second voltage measurement 1308 are represented as vertical bars on the voltage graph, and a first capacitance measurement 1310 and a second capacitance measurement 1312 are represented as vertical bars on the capacitance signal graph. In this example, the voltage measurements 1306, 1308 are associated with the first dome electrode and the capacitance measurements 1310, 1312 are associated with the second dome electrode.

When the dome switch is unpressed, the first electrode may remain electrically isolated, resulting in a low or zero voltage reading below the contact detection threshold 1302, as seen in the first voltage measurement 1306. Upon actuation, the dome apex may contact the first dome electrode, completing a circuit and producing a voltage spike, as seen in the second voltage measurement 1308, which exceeds the contact detection threshold 1302. This sharp voltage increase may be used to confirm a physical click event.

Simultaneously, the second electrode may detect the approach of the dome apex using capacitance sensing. In the unpressed state, the measured capacitance, as shown in measurement 1310, may remain below the proximity detection threshold 1304. As the dome nears its actuation apex, the second measurement 1312 rises above the threshold, indicating close proximity. Because the second dome electrode is not physically contacted, the capacitance increase is significant but remains within the sensor's operating range.

This example illustrates a hybrid sensing configuration in which physical contact is confirmed via voltage detection on one electrode, while proximity is tracked via capacitance changes on a separate electrode. A processor may generate a click event based on either or both signals, depending on system configuration. The combination of voltage and capacitance sensing may provide redundancy and allow for click detection to continue even if one sensing mode fails.

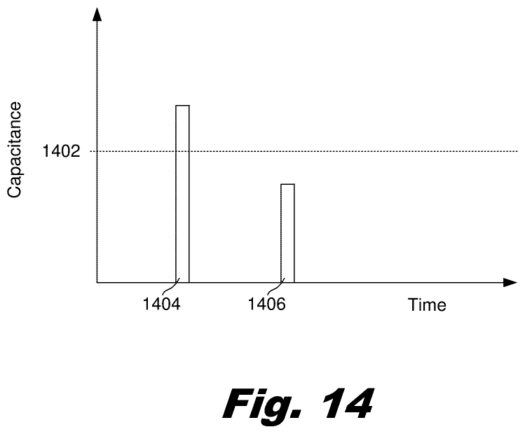

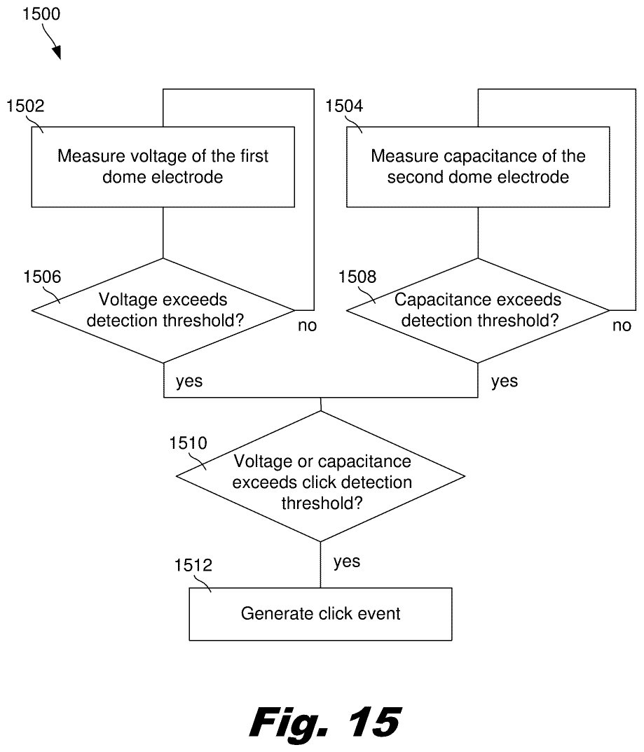

FIG. 14 depicts an example of a mutual capacitance signal graph, in accordance with the disclosure. The vertical axis represents measured capacitance between two electrodes arranged as a mutual capacitance sensor, and the horizontal axis represents time. A detection threshold 1402 is marked along the vertical axis. A first capacitance measurement 1404 and a second capacitance measurement 1406 are shown as bars at different time points.

In this example, the dome electrodes within a capacitive dome switch are arranged such that the dome apex does not physically contact either electrode. Instead, the mutual capacitance between the electrodes changes as the dome structure approaches, due to disruption of the shared electric field. The first measurement 1404 is taken when the dome is in its unpressed, resting state. At this point, the mutual capacitance remains above the detection threshold 1402, indicating no actuation.

As the dome is depressed and its apex nears the electrodes, the structure interferes with the electric field, reducing the measured mutual capacitance. This behavior is reflected in the second measurement 1406, which falls below the detection threshold 1402, indicating a proximity event which may be consistent with actuation.

In such configurations, a processor may monitor changes in mutual capacitance over time and generate a click event when the measured capacitance value falls below the detection threshold. Because mutual capacitance sensing may not involve physical contact in some cases, this configuration may reduce mechanical wear and improve the long-term durability of the switch.

FIG. 15 depicts an example of a method 1500 for generating a click event using a capacitive dome switch. This method 1500 may be performed based on the description of the devices, modules, and principles described in relation to FIGS. 1-14. During operation, a processor may measure 1502 a voltage of the first dome electrode of a dome switch. The processor may measure 1504 a capacitance of the second dome electrode of the dome switch. The processor may make a first determination 1506 whether the voltage exceeds a detection threshold and make a second determination 1508 whether the capacitance exceeds a detection threshold. If either the voltage or the capacitance do not exceed their respective detection thresholds, the processor may continue monitoring without further action. If one or both of the voltage or capacitance measurements exceeds their detection thresholds, the processor may make a third determination 1510 whether the signal, either voltage capacitance, or both, exceeds a stricter click detection threshold. This threshold may be tuned to indicate a more confident actuation state. If the click detection threshold is exceeded, the processor may generate 1512 a click event. This event may be used by downstream components to register user input, trigger a UI response, or initiate further signal processing.

This decision logic may enable redundancy and robustness in dome switch input detection. Voltage-based contact sensing may provide direct confirmation of actuation, while capacitance sensing adds failover support in cases where physical contact may be degraded, intermittent, or entirely absent. The dual path architecture may ensure that actuation is reliably captured even in suboptimal conditions.

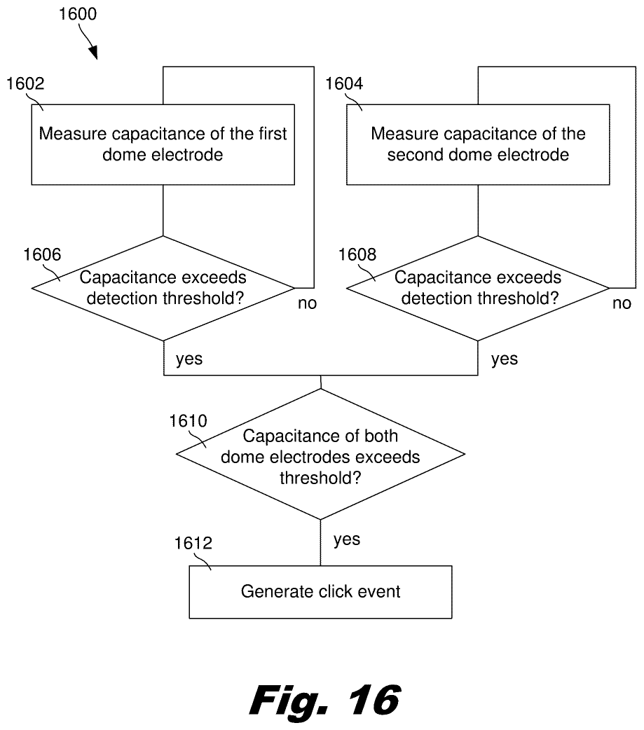

FIG. 16 depicts an example of a method 1600 for generating a click event using a capacitive dome switch. This method 1600 may be performed based on the description of the devices, modules, and principles described in relation to FIGS. 1-14. During operation, a processor may measure 1602 a capacitance of the first dome electrode of a dome switch. The processor may also measure 1604 a capacitance of the second dome electrode of the dome switch. The processor may make a first determination 1606 whether the capacitance of the first dome electrode exceeds a detection threshold and make a second determination 1608 whether the capacitance of the second dome electrode exceeds a detection threshold. If either capacitance measurement does not exceed its respective detection threshold, the processor may continue monitoring without further action. If both capacitance measurements exceed their detection thresholds, the processor may make a third determination 1610 whether the capacitance of both electrodes exceeds a stricter click detection threshold. This threshold may be tuned to indicate a more confident actuation state. If the click detection threshold is exceeded, the processor may generate 1612 a click event. This event may be used by downstream components to register user input, trigger a UI response, or initiate further signal processing.

This decision logic may improve reliability and robustness in dome switch input detection by using confirmatory capacitance increases on both sensing electrodes. Using dual self-capacitance measurements may reduce the likelihood of false positives cause by noise, parasitic interference, or unintended proximity. The combined signal condition may ensure that a click event is registered only when both electrodes independently confirm an actuation state.

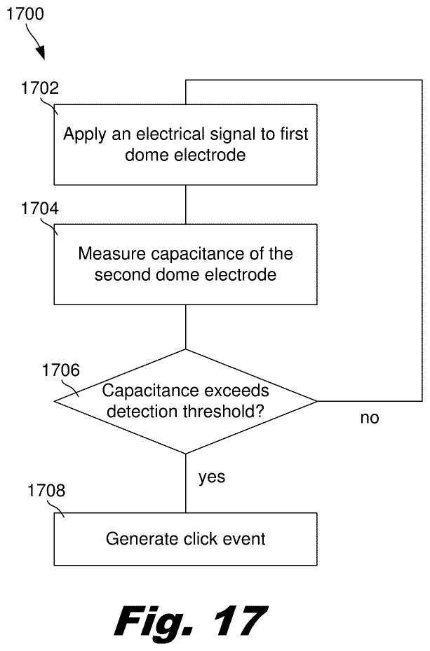

FIG. 17 depicts an example of a method 1700 for generating a click event using mutual capacitance sensing in a capacitive dome switch. This method 1700 may be performed based on the description of the devices, modules, and principles described in relation to FIGS. 1-14. During operation, a processor may apply 1702 an electrical signal to a first dome electrode. The processor may then measure 1704 the capacitance of a second dome electrode that is capacitively paired with the first electrode to form a mutual capacitance sensor. The processor may make a determination 1706 whether the measured mutual capacitance between the electrodes exceeds a detection threshold. In mutual capacitance systems, actuation of the dome structure may reduce the effective capacitance between the electrodes due to the interruption the shared electric field. If the measured capacitance does not exceed the detection threshold (e.g., does not fall below it in the case of a decreasing signal), the processor may continue monitoring without taking further action. If the threshold is exceeded, the processor may generate 1708 a click event. The click event may be used by downstream components to register user input, trigger a UI response, or initiate further signal processing.

This method may enable contactless detection of dome switch actuation and may improve durability by eliminating mechanical wear at the sensing interface. Mutual capacitance sensing may also provide greater resilience against environmental noise and interference, particularly in layered or shielded touchpad configurations.

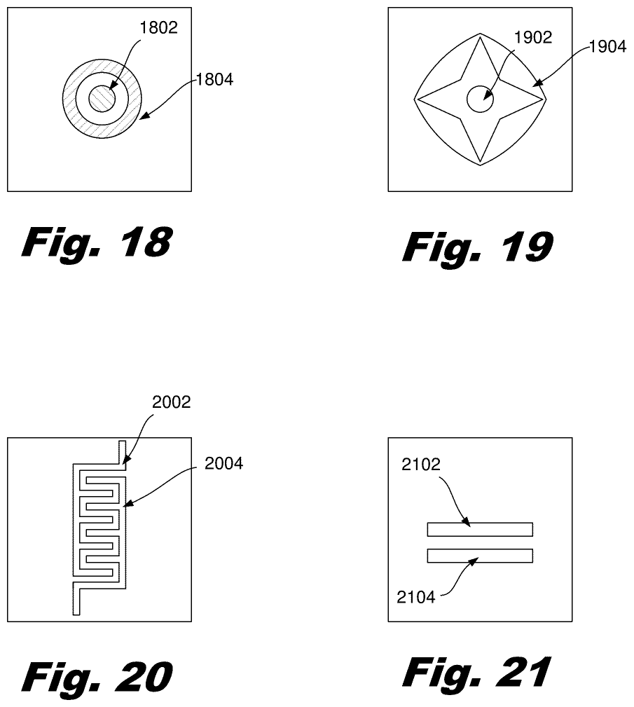

FIG. 18 depicts an example configuration of a first dome electrode 1802 and a second dome electrode 1804. The shape and positioning of the electrodes may vary depending on the operating mode of the capacitive dome switch. For example, in configurations that rely on both physical contact and capacitive sensing, one electrode may be centrally positioned while the other surrounds it peripherally.

In this example, the first dome electrode 1802 is circular and positioned at the center, while the second dome electrode 1804 forms a concentric ring around it. This arrangement may be particularly effective in capacitive dome switches that detect both physical contact and proximity.

FIG. 19 depicts another configuration in which a first dome electrode 1902 has a circular shape, and a second dome electrode 1904 has a patterned, concentric diamond shape. This geometry may enhance sensitivity to the proximity of the dome apex, providing improved resolution compared to a basic ring shape.

FIG. 20 depicts a configuration intended for capacitive dome switches that operate entirely through capacitive sensing, without relying on physical contact. In such implementations, the electrodes may be symmetrically arranged around the expected path of the dome apex.

In this example, a first dome electrode 2002 and a second dome electrode 2004 have interleaving comb structures. This pattern may improve sensitivity in mutual capacitance or dual self-capacitance configurations by increasing the effective sensing area and enhancing signal granularity.

FIG. 21 depicts a first dome electrode 2102 and a second dome electrode 2104 arranged in an aligned configuration. This geometry may be particularly well suited to mutual capacitance implementations, where one electrode (e.g., 2102) functions as a dedicated transmit electrode and is positioned closer to the dome apex during actuation to maximize the coupling effect.

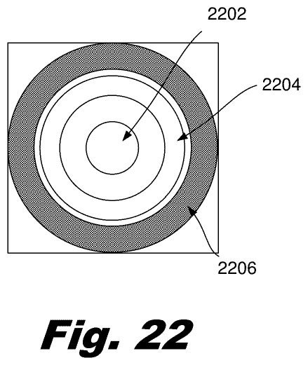

FIG. 22 depicts an example of a dome electrode configuration in accordance with the disclosure. In this example, a first dome electrode 2202 and second dome electrode 2204 are positioned within a shield 2206. The shield 2206 may be made of a material constructed to reduce or eliminate electromagnetic interference that may interfere with the operation of both dome electrodes 2202, 2204. By shielding the dome electrodes, a capacitive dome switch may have increased click detection accuracy.

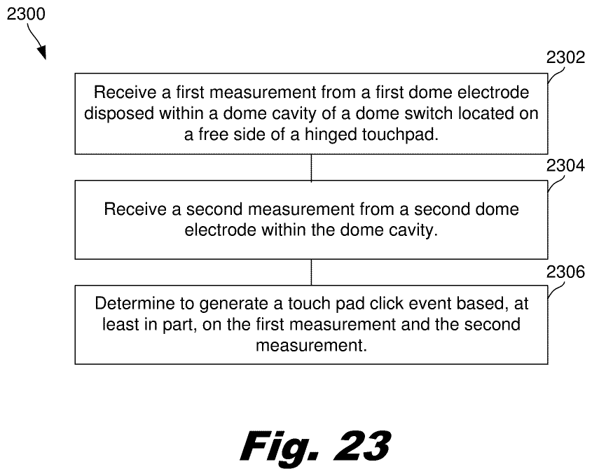

FIG. 23 depicts an example of a method 2300 for determining a click on a touchpad which incorporates a capacitive dome switch. This method 2300 may be performed based on the description of the devices, modules, and principles described in relation to FIGS. 1-22. A processor may receive 2302 a first measurement from a first dome electrode disposed within a dome cavity of a dome switch located on a free side of the hinged touchpad. The processor may receive 2304 a second measurement from a second dome electrode within the dome cavity. The processor may determine 2306 to generate a touch pad click event based, at least in part, on the first measurement and the second measurement.

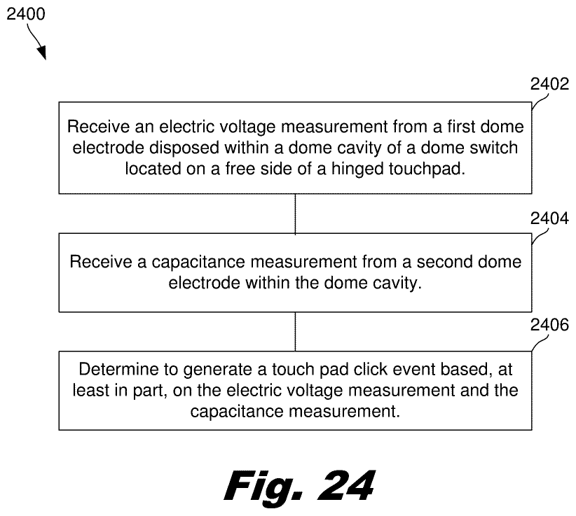

FIG. 24 depicts an example of a method 2400 for determining a click on a touchpad which incorporates a capacitive dome switch. This method 2400 may be performed based on the description of the devices, modules, and principles described in relation to FIGS. 1-22. A processor may receive 2402 an electric voltage measurement from a first dome electrode disposed within a dome cavity of a dome switch located on a free side of a hinged touchpad. The processor may receive 2404 a capacitance measurement from a second dome electrode within the dome cavity. The processor may determine 2406 to generate a touch pad click event based, at least in part, on the electric voltage measurement and the capacitance measurement.

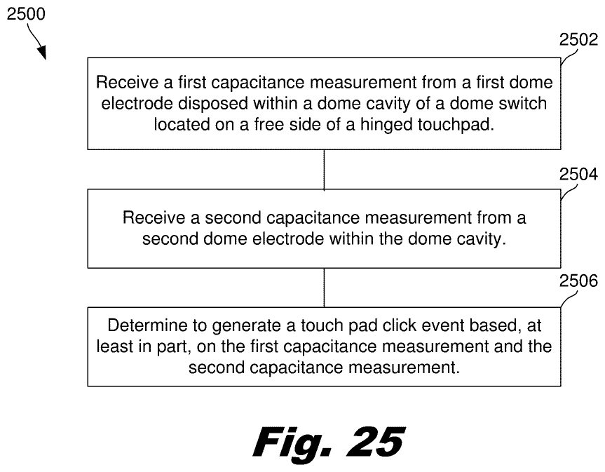

FIG. 25 depicts an example of a method 2500 for determining a click on a touchpad which incorporates a capacitive dome switch. This method 2500 may be performed based on the description of the devices, modules, and principles described in relation to FIGS. 1-22. A processor may receive 2502 a first capacitance measurement from a first dome electrode disposed within a dome cavity of a dome switch located on a free side of a hinged touchpad. The processor may receive 2504 a second capacitance measurement from a second dome electrode within the dome cavity. The processor may determine 2506 to generate a touch pad click event based, at least in part, on the first capacitance measurement and the second capacitance measurement.

It should be noted that the methods, systems, and devices discussed above are intended merely to be examples. It must be stressed that various embodiments may omit, substitute, or add various procedures or components as appropriate. For instance, it should be appreciated that, in alternative embodiments, the methods may be performed in an order different from that described, and that various steps may be added, omitted, or combined. Also, features described with respect to certain embodiments may be combined in various other embodiments. Different aspects and elements of the embodiments may be combined in a similar manner. Also, it should be emphasized that technology evolves and, thus, many of the elements are exemplary in nature and should not be interpreted to limit the scope of the invention.

Specific details are given in the description to provide a thorough understanding of the embodiments. However, it will be understood by one of ordinary skill in the art that the embodiments may be practiced without these specific details. For example, well-known circuits, processes, algorithms, structures, and techniques have been shown without unnecessary detail in order to avoid obscuring the embodiments.

Also, it is noted that the embodiments may be described as a process which is depicted as a flow diagram or block diagram. Although each may describe the operations as a sequential process, many of the operations can be performed in parallel or concurrently. In addition, the order of the operations may be rearranged. A process may have additional steps not included in the figure.

Having described several embodiments, it will be recognized by those of skill in the art that various modifications, alternative constructions, and equivalents may be used without departing from the spirit of the invention. For example, the above elements may merely be a component of a larger system, wherein other rules may take precedence over or otherwise modify the application of the invention. Also, a number of steps may be undertaken before, during, or after the above elements are considered. Accordingly, the above description should not be taken as limiting the scope of the invention.

1. An electronic device, comprising:
a capacitance module;
a set of capacitance electrodes disposed on a first layer of the capacitance module;
a dome switch connected to an underside surface of the capacitance module;
the capacitance module having a hinged side connected to a connecting surface of the electronic device and a free side opposite to the hinged side;
the dome switch comprising:
a dome element comprised of an elastically deformable material;
the dome element having:
a dome structure having a base attached to the underside;
the dome structure forming a collapsible surface;
the dome structure and the underside surface of the capacitance module define a cavity;
the dome element being flexible to move the collapsible surface into the cavity towards the underside surface.

2. The electronic device of claim 1, further comprising a first dome electrode on the underside surface and positioned within the cavity.

3. The electronic device of claim 2, wherein the collapsible surface of the dome element is constructed to form an electrical connection with the first dome electrode when an actuation force causes the collapsible surface to make physical contact with the first dome electrode.

4. The electronic device of claim 2, wherein the collapsible surface of the dome is constructed to move towards the first dome electrode but not make physical contact with the first dome electrode.

5. The electronic device of claim 4, further comprising a dielectric positioned between the collapsible surface of the dome structure and the first dome electrode in the cavity.

6. The electronic device of claim 2, further comprising a processor in communication with the first dome electrode and memory;
wherein the memory includes programmed instructions that cause the processor, when executed, to:
take a first measurement with the first dome electrode;
determine to generate a click event based, at least in part, on the first measurement.

7. The electronic device of claim 6, further comprising a second dome electrode.

8. The electronic device of claim 7, wherein the programmed instructions are configured to cause the second dome electrode to take a second measurement.

9. The electronic device of claim 8, wherein determining whether to generate a click event includes comparing the first measurement and second measurement against predetermined threshold values.

10. The electronic device of claim 8, wherein the first measurement is an electric voltage measurement and the second measurement is a capacitance measurement.

11. The electronic device of claim 8, wherein the first measurement is a capacitance measurement and the second measurement is a capacitance measurement.

12. The electronic device of claim 8, further comprising programmed instructions that cause the processor, when executed, to:
apply an electrical signal to the first dome electrode;
take a first capacitance measurement with the second dome electrode;
determine whether to generate a click event based, at least in part, on the first capacitance measurement.

13. The electronic device of claim 12, wherein the programmed instructions further cause the processor, when executed, to take a second capacitance measurement after taking the first capacitance measurement.

14. The electronic device of claim 13, wherein determining whether to generate a click event includes comparing the first capacitance measurement and the second capacitance measurement against predetermined threshold values.

15. The electronic device of claim 13, wherein determining whether to generate a click event includes comparing the first capacitance measurement to the second capacitance measurement.

16. The electronic device of claim 7, wherein the second dome electrode is disposed around the first dome electrode in a concentric ring shape wherein the space between the first dome electrode and the second dome electrode forms an annular shape.

17. A method for determining a click input on a capacitance module, comprising:
receiving a first measurement from a first dome electrode disposed within a dome cavity of a dome switch located on a free side of a hinged touchpad;
receiving a second measurement from a second dome electrode within the dome cavity;
determining to generate a touch pad click event based, at least in part, on the first measurement and the second measurement.

18. A computer-program product for determining a click input on a capacitance module; the computer-program product comprising a non-transitory computer-readable medium storing instructions executable by a processor to:
receive a first measurement from a dome electrode disposed within a dome cavity of a dome switch located on a free side of a hinged touchpad;
receive a second measurement from a second dome electrode within the dome cavity;
determine to generate a touch pad click event based, at least in part, on the first measurement and the second measurement.

19. The computer-program product of claim 18, wherein the first measurement is an electric voltage measurement and the second measurement is a capacitance measurement.

20. The computer-program product of claim 18, wherein the first measurement is a capacitance measurement and the second measurement is a capacitance measurement.
